(19) United States
(12) Patent Application Publication
(10) Pub. No.: US 2009/0160573 A1
(43) Pub. Date: Jun. 25, 2009

(54) GFCI-Compatible Circuit for Plasma Cutting System

(75) Inventors: Anthony Van Bergen Salsich, Appleton, WI (US); James Frederic Plamann, Appleton, WI (US)

Correspondence Address: FLETCHER YODER (ILLINOIS TOOL WORKS INC.), P.O. BOX 692289, HOUSTON, TX, 77269-2289, US

(73) Assignee: ILLINOIS TOOL WORKS, INC., Glenview, IL (US)

(21) Appl. No.: 11/960,466

(22) Filed: Dec. 19, 2007

(51) Int. Cl. H03H 7/42; B23K 15/02

(52) U.S. Cl. 333/25; 219/482

(57) ABSTRACT

In one embodiment, a system is provided that includes a GFCI compatibility control configured to filter noise, improve symmetry between lines, or a combination thereof, when connecting a device to a GFCI-protected power source. In another embodiment a circuit for a torch power unit is provided that includes an inductor comprising a first coil and a second coil, wherein the total inductance for the first coil is substantially the same as the total inductance for the second coil, and a plurality of capacitors coupled to both the first and second coils. Another system is provided that includes a torch power unit. The torch power unit includes a compressor, a motor coupled to the compressor, and a GFCI compatibility control configured to filter noise, improve symmetry between lines, or a combination thereof, when connecting a device to a GFCI-protected power source.

### BACKGROUND

The invention relates generally to metal cutting and welding systems, such as plasma cutting torches, metal inert gas (MIG) torches, stick welding systems, and so forth.

Some torch systems may be portable and only require a power source for operation. As portable torch systems become smaller and less costly to manufacture, such systems may be targeted at the consumer market. To ensure a safe and useful consumer torch system, it is desirable for systems to meet all the demands of a consumer device. For example, consumer torch systems may use alternating current (AC) provided by an AC power grid in a residence or place of business, as opposed to industrial locations having power sources particularly well suited for torch systems and other industrial equipment. In addition, safety regulations or safe practices usually require a ground fault circuit interrupt (GFCI) in the internal power distribution systems in residential and other non-industrial locations. Unfortunately, a portable torch system used in the consumer market may be incompatible with GFCI's and other components of residential and non-industrial power distribution systems.

### BRIEF DESCRIPTION

In one embodiment, a system is provided that includes a GFCI compatibility control configured to filter noise, improve symmetry between lines, or a combination thereof, when connecting a device to a GFCI-protected power source.

In another embodiment, a circuit for a torch power unit is provided that includes an inductor comprising a first coil and a second coil, wherein the total inductance for the first coil is substantially the same as the total inductance for the second coil; and a plurality of capacitors coupled to both the first and second coils.

In another embodiment, a system is provided that includes a torch power unit. The torch power unit includes a compressor, a motor coupled to the compressor, and a GFCI compatibility control configured to filter noise, improve symmetry between lines, or a combination thereof, when connecting a device to a GFCI-protected power source.

A method of operation of a torch power unit is provided that includes filtering noise, improving symmetry between lines of a power source, and increasing the power factor of input power from the power source.

### DRAWINGS

These and other features, aspects, and advantages of the present invention will become better understood when the following detailed description is read with reference to the accompanying drawings in which like characters represent like parts throughout the drawings, wherein:

FIG. 1 is a partial perspective view of an exemplary plasma cutting system having a gas compressor in accordance with embodiments of the present invention;

FIG. 2 is another partial perspective view of the plasma cutting system as illustrated in FIG. 1, wherein an entire side panel assembly is removed to further illustrate various internal features in accordance with embodiments of the present invention;

FIG. 3 is a block diagram of a GFCI-compatible and power factor correction circuit in a plasma cutting system in accordance with an embodiment of the present invention; and

FIG. 4 is a circuit diagram of the GFCI-compatible and power factor correction circuit of FIG. 3 in accordance with an embodiment of the present invention.

### DETAILED DESCRIPTION

Ground fault circuit interrupter (GFCI) devices are designed to protect users from accidental shock when using devices connected to the AC mains. A GFCI detects “leakage current,” i.e. unbalanced current flow between a live or phase line and a neutral line of an AC power source. An unbalanced current flow may be the result of a hazardous condition, such as current flowing to ground through a person, if the person is in contact with the circuit of a device. If the detected leakage current exceeds a certain threshold, a GFCI device can ‘interrupt” the circuit, i.e. stop current flow through the circuit. Because of the wide implementation of GFCI devices, such devices may be used with a variety of systems, such as those not originally intended for use in residential power grids. Systems may include portable torch power units targeted to the consumer market, such as welding and/or cutting systems. These systems may include a variety of tools, such as plasma cutting torches, MIG torches, stick welders, etc.

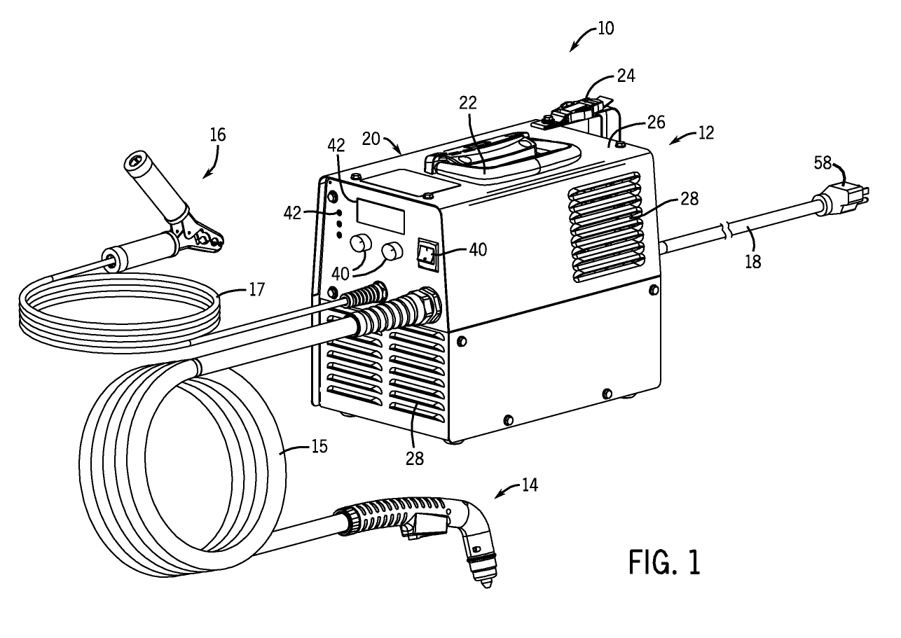

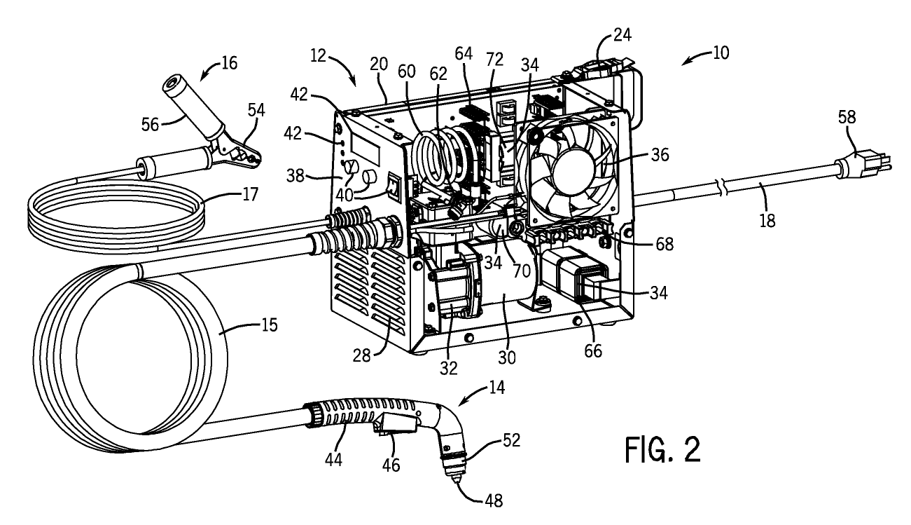

Referring now to the drawings, FIGS. 1 and 2 are partial perspective views illustrating an embodiment of a portable plasma cutting system 10. Specifically, FIG. 1 illustrates the system 10 with access panels completely assembled to close internal components, whereas FIG. 2 illustrates an entire side panel assembly removed to provide a better view of the internal features and components of the system 10. As discussed in further detail below, embodiments of the system 10 include a compressor controller and one or more profiles configured to start-up and shutdown a compressor by accelerating through one or more resonance points.

The illustrated plasma cutting system 10 includes a torch power unit 12 coupled to a plasma torch 14 and a work piece clamp 16 via a torch cable 15 and a work piece cable 17, respectively. The torch power unit 12 may be coupled to a power source (e.g., a power grid or a motor-driven generator) via a power cable 18. The power source may provide a pilot current to a cathode, such as a movable electrode, and to the anode, such as the nozzle of the torch 14, that are forced into contact via a spring. After electrical current begins to flow from the electrode to the nozzle of the torch 14, gas or air supplied to the torch 14 counteracts the spring force and moves the electrode away from the nozzle. This breaks the electrical contact between the electrode and the nozzle and creates the pilot arc. Also, as the electrode moves away from the nozzle, it opens a nozzle orifice (connected to the air supply), and a plasma jet is created. The plasma jet causes the arc to transfer (at least in part) to the work piece held by the clamp 16, thus initiating cutting. Electronics in the power source sense when the arc has transferred and then supply a main cutting current of greater amperage after the transfer has occurred. Also, the tip of the torch 14 is disconnected (electrically), interrupting the pilot current path. Thus, the current is used to cut the work piece, and follows a path including the positive terminal, the work piece and the electrode. For example, the power unit 12 may be configured to supply a suitable voltage and current to create an electrical circuit from the unit 12, along the cable 15 to the torch 14, across a gap between the torch 14 and a work piece (e.g., as an electrical arc), through the work piece to the clamp 16, through the cable 17 back to the unit 12. In alternate embodiments, a non-moving electrode torch may be used in which a pilot arc is created via a high voltage and/or high frequency circuit, so that the high voltage may cause the pilot arc to jump from the non-moving electrode to the nozzle. In yet other embodiments, any suitable torch and starting technique may be used.

The power unit 12 includes an enclosure 20 defining a generally closed volume to support various circuits, sensor features, control features, and gas supply features (e.g., air compressor). As discussed in detail below, the illustrated system 10 includes a variety of features to improve portability, serviceability, reliability, and control of the plasma torch 14 and the components within the single enclosure 20 of the system 10. For example, the system 10 may include sensors and controls to adjust the power unit 10 to account for various conditions, e.g., altitude, temperature, pressure, and so forth. The illustrated system 10 also may include a handle 22 on the top side of the enclosure 20 to enable easier transportation of the system 10. The illustrated system 10 also may include a latching mechanism 24 that may secure the torch 14, the cable 17, the clamp 16, and/or the power cable 18. The enclosure 20 may also include vents 28 to relieve heat and/or pressure inside the system 10. Additional vents may be located on other panels of the enclosure 20.

To provide for operation of the plasma torch 14, the system 10 may include a compressor motor 30, such as a DC or AC motor that may include brushed, brushless, switched reluctance, or any other suitable type of motor, and a compressor 32. For example, the compressor 32 may include a positive displacement compressor, such as reciprocating compressor (e.g., piston-cylinder), a rotary screw compressor (e.g., helical screws to compress a gas continuously without a storage tank), a diaphragm compressor, or the like. In certain embodiments, the system 10 may include a flow or pressure meter or like sensor configured to monitor output of the compressor 32. The system 10 also may include sensors, such as a pressure sensor, a temperature sensor, or a combination thereof, to provide feedback used to adjust the motor 30, the compressor 32, power electronics 34, or a combination thereof. The power electronics 34 may be configured to condition and provide power to the torch 14 and the compressor 32, and may include transformers, circuit boards, and/or other components. A fan 36 may also be included inside the system 10 to provide air circulation and cooling to the system 10. Additionally, as depicted in FIG. 2, the fan 36 may be located next to one of the vents 28 to optimize air circulation. Additional fans 36 may be included at other locations inside or outside the enclosure 20.

In the illustrated system 10, a control panel 38 is included at an end of the power unit 12. The control panel 38 may include various control inputs, indicators, displays, electrical outputs, air outputs, and so forth. In an embodiment, a user input 40 may include a button, knob, or switch configured to enable selection of a mode of operation (e.g., plasma cut, gouge, etc.), power on/off, an output current level, gas (e.g., air) flow rate, gas (e.g., air) pressure, gas type, a work piece type, a control type (e.g., manual or automatic feedback control), or a combination thereof. The control panel 34 may also include various indicators 42 to provide feedback to the user. For example, the indicators 42 may include one or more light emitting diodes (LED) and/or liquid crystal displays (LCD) to display on/off status, current level, voltage level, gas (e.g., air) pressure, gas (e.g., air) flow, environmental conditions (e.g., altitude, temperature, pressure, etc.), or any other parameter. Additionally, the indicators 42 may include an LED or LCD that displays a trouble or warning indicator if there is a problem with the system 10. Embodiments of the control panel 38 may include any number inputs and outputs, such as welding methods, air compressor settings, oil pressure, oil temperature, and system power.

Further, the user inputs 40 and indicators 42 may be electrically coupled to control circuitry and enable a user to set and monitor various parameters of the system 10. For example, the indicators 42 may display environmental conditions (e.g., altitude, temperature, pressure, etc.) that prompt a user to manually adjust the current, voltage, gas flow rate, gas pressure, or other operational parameters, or a combination thereof. The indicators 42 also may prompt a user to enable the system to perform automatic adjustments in view of the sensed environmental conditions. For example, one of the inputs 40 may enable a user to select an automatic feedback control mode based on environmental conditions and/or sensed parameters of the system 10 (e.g., compressor output).

The plasma torch 14 includes a handle 44, a locking trigger 46, a tip 48, a retaining cap 52, as well as an electrode inside the torch 14. The clamp 16 comprises an electrically conductive material clamping portion 54 having insulated handles 56. The power cable 18 includes a plug 58 for connection to a power source such as a wall socket or a motor-driven generator. The plug 58 may be configured to work with a variety of sockets or outlets, and the system 10 may receive different power sources, such as AC 50/60 Hz, 400 Hz, single or three phase 120V, 230V, 400V, 460V, 575V, etc.

Turning now in more detail to FIG. 2, the system 10 includes the fan 36, the gas compressor 32, a heat exchanger 60, pneumatic coupling 62, and heat sinks 64. Additionally, the power electronics 34 includes a ground fault circuit interrupt (GFCI) compatible circuit, a dual inductor 66, primary terminal block 68, bus capacitor 70, and transformer 72. Additionally, the system 10 may include additional inductors, terminals capacitors, transformers, or other electrical components and is not limited to the components illustrated in FIGS. 1-2.

As mentioned above, the gas compressor 32 may be a reciprocating compressor (e.g., piston-type compressor), a diaphragm compressor, or a rotary screw compressor. In the illustrated embodiment, the gas compressor 32 is a single stage reciprocating compressor. The compressor 32 may include or may be connected to the DC or AC motor 30 that is connected to power electronics 34 inside the system 10, such that the motor 30 drives the compressor 32. The gas compressor 32 may be rigidly mounting inside the enclosure 20 using compressor mounts such as rubber mounts, plastic mounts, metal mounts, or any other material. The compressor mounts may be configured to dampen vibrations of the compressor or to allow slight movement of the compressor during operation.

In the illustrated embodiment, the gas compressor 32 intakes and compresses air directly from the atmosphere, such as via filter, and may use one of the vents 28 as an intake vent to enable air to flow into the compressor 32. The gas used by the compressor 32 may be any gas, such as nitrogen, argon, hydrogen, oxygen, or any combination thereof. Accordingly, the gas compressor 32 may provide a direct supply of compressed gas (e.g., air) on-demand to a desired application, such as the plasma torch 14. Thus, the torch 14 may consume air directly from the unit 12 without the air being compressed into a tank downstream of the compressor 32. However, alternative embodiments may include an air tank configured to store the compressed air.

To ensure reliability and performance for the system 10, various temperature sensors (e.g., thermistors) may be included inside the enclosure 20 to measure the temperature of various components. For example, the system 10 may include a temperature sensor configured to measure the temperature of the motor 30, the compressor 32, the power electronics 34, atmospheric air, and so forth. In addition to each temperature sensor, the system 10 may include control and/or monitoring logic to receive signals from the temperature sensors and perform the appropriate action or indication. For example, if the signal from one or more of the temperature sensors (e.g., thermistors) exceeds a threshold temperature or voltage for a component, then the control and monitoring logic may provide a visual warning by activating a LED or LCD 42 on the control panel 38. If the signal from a temperature sensor (e.g., thermistor) exceeds another threshold temperature or voltage and/or the signal remains above the threshold for a specific duration, then the control and monitoring logic may shutdown the system 10 or that component. The control and monitoring logic may prevent use of the system 10 until the signals from the temperature sensors fall below the threshold levels.

The system 10 may also include control circuitry to coordinate functions of the system components. For example, the system 10 may include control circuitry in the vicinity of the control panel 34. In one embodiment, the control circuitry may include a processor, memory, and software code configured to control and/or coordinate operation of the system 10.

The system 10 may include cooling components such as the heat sinks 64 and may include active cooling via the fan 36. The heat sinks 64 may be mounted such that airflow from the fan 36 circulates air around the heat sinks, further enhancing the cooling capability of the heat sinks 64. As discussed above, additional fans may be included in other locations in the system 10. Similarly, additional heat sinks may be placed inside the system 10 depending on those areas that need passive cooling and/or cannot be cooled by any of the fans in the system 10. Thus, in other embodiments, the system 10 may include any number and combination of active and passive cooling components.

During operation of the system 10, a user first connects the system to a power source, such as a wall socket, via the power cable 18 and the plug 58. A user may then turn on the system 10 via the user input 40. The compressor 32, fan 36, and other components of the system 12 receive power from the power electronics 34 and begin operation after the user input is activated and the control circuitry calls for operation. A user then attaches the clamp 16 to a work piece (e.g., metal or other material) to be cut. To begin cutting the work piece, the user places the cutting torch 14 adjacent the work piece and activates the trigger 46, which may involve raising a locking mechanism to free the trigger 46 before depressing the trigger 46. Compressed gas from the gas compressor 32 passes through the heat exchanger 60 and through the torch cable 15 and out the tip 48 of the torch 14. As discussed above, a pilot current may be supplied between a moveable electrode and the nozzle of the torch 14, thus establishing a pilot arc when the moveable electrode is pushed away from the nozzle of the torch 14 by the gas supplied by the compressor 32. As the electrode moves away from the nozzle of the torch, gas flowing through the torch 14 is energized into a plasma jet which in turn transfers the arc to the work piece.

The electrical arc heats up the gas from the compressor 32, converting it to plasma that is hot enough to cut the work piece. As the user moves the torch 14 across the work piece by dragging, using a drag shield, standoff guide, or the like, the material is cut as the plasma moves through the material. The thickness of the material being cut may be limited by the power of the system 10, the output of the compressor 32, and the torch 14. In addition to supplying the plasma, the compressed gas from the compressor 32 cools the torch 14 and blows away molten material (e.g., molten metal). At the end of the cut, the user releases the trigger 46 of the torch 14. Gas may continue to flow through the torch 14 for a period of time sufficient to cool the consumables, in a state known as “postflow.” The postflow cools the torch 14 and ensures that any remaining material is blown away.

Embodiments of the present invention may include a circuit to ensure that the system 10 and other similar systems (e.g., plasma cutting, welding, or induction heating systems) are compatible with GFCI devices. The system 10 and other torch systems may be designed for or targeted to the consumer market, thus increasing the likelihood that such systems will be used in a power distribution system that includes GFCI devices. For example, as discussed above, the power cable 18 and plug 58 may be connected to a wall socket to receive power from an AC power source, such as AC power grid that distributes power to residential and non-industrial areas. The power electronics 34 may include power converting circuitry to convert the received AC power to DC power usable by the motor 30, compressor 32, and other components in the system 10. However, without the circuit 80 discussed in detail below, the power electronics 34 may have a power factor (ratio of real power to apparent power) unsuitable for optimally utilizing AC power from residential or non-industrial power sources. For example, the bus capacitor 70 or the inductor 66 may generate reactive power and cause a lagging or leading power factor respectively. A lower power factor for the power electronics 34, either as a result of capacitive loads, such as capacitors, or as a result of inductive loads, such as inductors, motors, or transformers, affects the efficiency of power usage from the AC power source. Further, use of a rectifier and a capacitor together may cause harmonics in the current on the power lines that may also lower the power factor. The higher the power factor of the power electronics 34 or other circuits in the system 10, the more efficiently power may be utilized (real to apparent power ratio closer to unity).

Further, without the circuit 80 discussed in detail below, the power electronics 34 in the system 10 may accidentally trip the GFCI's in a residential or non-industrial location. In a typical wall socket used to distribute AC power to a device, one conductor/line may be a phase or “live” conductor, and the other conductor/line may be a neutral conductor/line. If a GFCI detects a current imbalance between the phase line and the neutral line, the GFCI activates or “trips” and disconnects the circuit, interrupting the flow of power to the wall socket and to the device. The difference in current between the phase or “live” line and the neutral line may be referred to as leakage current. GFCI's for residential or non-industrial locations may have a leakage current threshold, after which the GFCI's activate if the leakage current rises above the threshold. For example, the leakage current threshold for a typical residential GFCI may be around 5 mA.

Again, without the circuit 80 discussed in detail below, if a torch system such as the plasma cutting system 10 is used on a circuit containing a GFCI, the power electronics 34 and power conversion circuitry may result in accidental or “nuisance” tripping of a GFCI. In another example, power converting circuitry in the power electronics 34 may generate high frequency noise that can trip a GFCI. Thus, an operator of the system 10 would need to reset the GFCI before the system 10 could be used, yet can do nothing to eliminate future nuisance tripping of the GFCI. Additionally, the relatively low power factor described above, as well as nuisance tripping of the GFCI, results in a torch system (e.g., plasma cutting system) that is unsuitable for use by a consumer in a residential or other non-industrial location.

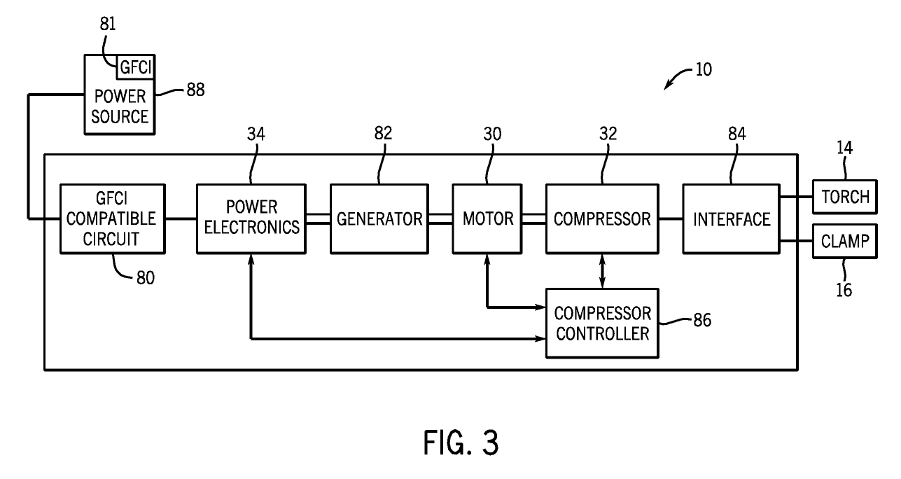

FIG. 3 is a block diagram of the system 10 that includes a GFCI-compatible circuit 80 in accordance with an embodiment of the present invention. The GFCI-compatible circuit 80 includes filtering to reduce noise on the lines of an AC power source, and the circuit 80 may also include power factor correction to increase utilization efficiency of the incoming power. The illustrated embodiment includes the power electronics 34 which may include the power converting circuitry responsible for high frequency noise and/or leading or lagging power factor. As discussed above, the high frequency noise may result in leakage current and possible nuisance tripping of a GFCI 81. The embodiment in FIG. 3 also includes a power generator 82, the motor 30, the compressor 32, an interface 84, a compressor controller 86, the torch 14 and the clamp 16.

The compressor 32 is driven by the motor 30, which may be controlled by the compressor controller 86. As discussed above, the motor 30 may be an electric motor, such as a DC motor, or a gas combustion engine. For example, the motor 30 may include a two-stroke or four-stroke spark-ignition engine, which includes one or more reciprocating piston in cylinder assemblies, a carburetor or fuel injection system, and so forth. Some embodiments of the system 10 may include the power generator 82 built-in or integrally disposed within the enclosure 20 of the power unit 12. Thus, the motor 30 may drive both the compressor 32 and the electrical generator 82, thereby making the power unit 12 completely portable for use in remote locations. However, other embodiments may exclude the generator 82 to reduce the size, weight, and cost of the power unit 12. Additionally, power electronics 34 provide the power management functions for the system 10. In some embodiments, the power electronics 34 may include a plasma cutting circuit, a welding circuit, an induction heating circuit, a user input/interface circuit, a power generator circuit (e.g., if the unit 12 includes the generator 82), or a combination thereof.

The compressor controller 86 may control and monitor the speed or output of the compressor 32 and/or motor 30, and may also control and monitor the voltage, current, or other parameter of the compressor 32 and/or motor 30. The compressor controller may change these parameters in response to signals received by a user through the interface 84. For example, if a user activates or turns on the system 10 and the compressor 32 through the control panel/interface 84, the compressor controller 86 may start-up the motor 30 and the compressor 32. Similarly, a shutdown signal received from the interface 84 in response to a user turning off the system 10 would result in the compressor control 86 shutting down the motor 30 and compressor 32.

The illustrated system 10 is connected to a power source 88, such as an AC power grid via a wall socket, as discussed above. The power distribution circuitry in such a location may also include one or more GFCI's 81 which may be configured at various points in the circuit for safety reasons or regulations. To reduce or eliminate nuisance tripping of the GFCI 81, the illustrated embodiment of the system 10 includes the GFCI-compatible circuit 80. The circuit 80 filters the noise generated by the power converter of the power electronics 34 and aids in reducing the current difference between the phase line of the AC power source 88 and the neutral line of the power source 88. The circuit 80 may also include passive power factor correction to deal with capacitive or inductive loads in the power electronics 34 that may cause leading or lagging power factors respectively. In another embodiment, the circuit 80 may include software control to adjust parameters or components of the circuit 80 to filter noise and/or adjust current symmetry/flow between the two lines of the AC power source 88.

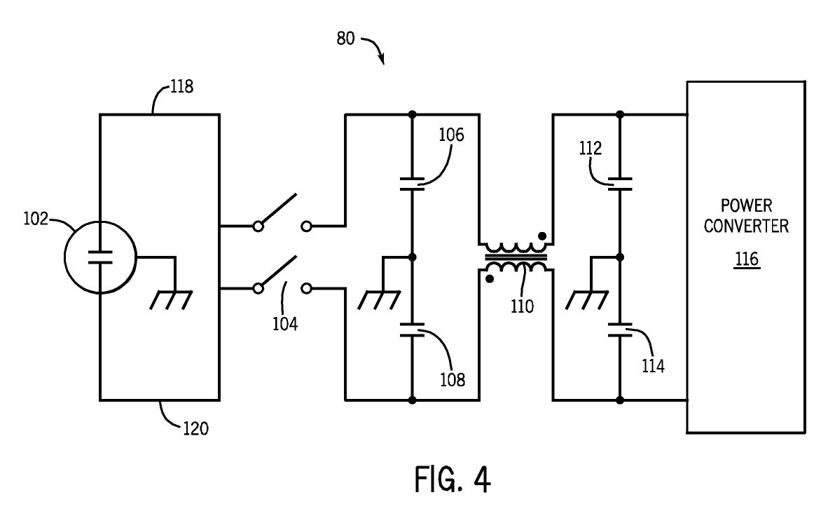

Turning to FIG. 4, a circuit diagram of the GFCI-compatible circuit 80 is depicted in detail in accordance with an embodiment of the present invention. The circuit includes a connection 102 to an AC power source. The circuit includes a two-pole switch 104, capacitors 106 and 108, and an inductor 110. After the inductor 110, the circuit includes capacitors 112 and 114. The circuit 80 is shown coupled to a power converter 116, which may a part of the power electronics 34.

The inductor 110 may provide the primary functions of both filtering the power and passively increasing the power factor of the circuit 80. In one embodiment, the inductor 110 may be a solenoidal inductor and, instead of a single coil, arranges two coils around a common core. Each coil of the inductor 110 is connected to the two lines of the AC power source, a phase conductor/line 118 and a neutral conductor/line 120. In such a configuration, the inductor 110 may behave as a differential mode inductor, such that the inductances of the first coil and the second coil may be substantially the same, thus gaining symmetry on the line coupled to the first coil and the line coupled to the second coil. In other embodiments, the inductance of the first coil may be greater than, less than, or substantially the same as the second coil. The dual coils of the inductor 110 filter high frequency noise from the power converter from both lines 118 and 120 of the AC power source and aid in keeping the current symmetrical between the phase line 118 and the neutral line 120, thus minimizing the current difference or leakage current between the two lines. Reducing the leakage current reduces or eliminates the possibility of accidental or nuisance tripping of a GFCI. Further, the inductance may compensate for any capacitive loads and improve the power factor of the entire circuitry of the system 10 by reducing harmonic content on the power lines. Alternatively, in other embodiments, the inductor 110 may be two separate coils wound on their own cores, although at the expense of adding cost and weight to the system.

The capacitors 106, 108, 112, and 114 aid in filtering noise from the power converter 116. The two-pole switch 104, which acts as the main power cutoff switch, may also prevent nuisance tripping of the GFCI when a system 10 using the circuit 80 is switched off. If the system 10 is switched off, the two-pole switch 104 being off isolates the phase line 118 of the AC power source 102 as well as the neutral line 120.

It should be appreciated that the GFCI-compatible and power factor correction circuit 80 described here is applicable to any portable welding-type or torch system, such as welders, plasma cutting/gouging, induction heating, etc. For example, the circuit 80 may be incorporated into a variety of systems that include an engine, generator, and/or compressor. Additionally, the circuit may be retrofitted to an existing system to add GFCI-compatibility.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A system, comprising:
a GFCI compatibility control configured to filter noise, improve symmetry between lines, or a combination thereof, when connecting a device to a GFCI-protected power source.

2. The control of claim 1, wherein the GFCI compatibility control comprises a circuit.

3. The control of claim 2, wherein the circuit comprises an inductor comprising a first coil and a second coil, wherein the total inductance for the first coil is substantially the same as the total inductance for the second coil,

4. The control of claim 2, wherein the circuit comprises an inductor comprising a first coil and a second coil, wherein the total inductance for the first coil is greater than or less than the total inductance of the second coil.

5. The control of claim 1, wherein the GFCI compatibility control is configured to improve symmetry between neutral and phase lines of an AC power source.

6. The control of claim 1, wherein the GFCI compatibility control is configured to filter noise associated with circuit of a device.

7. A circuit for a torch power unit, comprising:
an inductor comprising a first coil and a second coil, wherein the total inductance for the first coil is substantially the same as the total inductance for the second coil; and
a plurality of capacitors coupled to both the first and second coils.

8. The circuit of claim 7, comprising a power switch coupled to the plurality of capacitors.

9. The circuit of claim 8, wherein the two-pole power switch is configured to be in an OFF position when the torch power unit is off.

10. The circuit of claim 7, wherein the first coil and the second coil of the inductor are configured to connect to two or more lines of an alternating current power source.

11. The circuit of claim 7, wherein the first coil is wound on a first core and the second coil is wound on a second core.

12. A system, comprising:
a torch power unit, comprising:
a compressor;
a motor coupled to the compressor; and
a GFCI compatibility control configured to filter noise, improve symmetry between lines, or a combination thereof, when connecting a device to a GFCI-protected power source.

13. The system of claim 12, wherein the GFCI compatibility control comprises a circuit.

14. The system of claim 12, wherein the circuit comprises an inductor comprising a first coil and a second coil, wherein the total inductance for the first coil is substantially the same as the total inductance for the second coil.

15. The system of claim 12, wherein the circuit comprises an inductor comprising a first coil and a second coil, wherein the total inductance for the first coil is greater than or less than the total inductance of the second coil.

16. The system of claim 12, wherein the torch power unit comprises a plasma cutting circuit, a welding circuit, an induction heating circuit, or a combination hereof.

17. The system of claim 12, wherein the torch power unit comprises a power generator.

18. The system of claim 12, comprising a motor coupled to both the power generator and the compressor.

19. A method of operation of a torch power unit, comprising:
filtering noise;
improving symmetry between lines of a power source; and
increasing the power factor of input power from the power source.

20. The method of claim 19, wherein increasing the power factor comprises increasing the power factor of input power from a power source via a circuit comprising an inductor coupled to a phase conductor of the power source and a neutral conductor of the power source.

21. The method of claim 19, wherein the inductor is coupled to the phase conductor and the neutral conductor of the power source such that the inductances are additive.

22. The method of claim 19, comprising filtering noise generated by a power converter coupled to the circuit via the inductor.

23. The method of claim 19, wherein filtering noise comprises filtering with a plurality of capacitors.

24. The method of claim 19, comprising reducing capacitive imbalance on an alternating current power source when the torch power unit stops drawing power from the alternating current power source.

25. The method of claim 19, wherein reducing capacitive imbalance comprises preventing capacitive imbalance via a two-pole switch, wherein the two-pole switch is in an OFF position when the torch power unit is turned off.
